(19) United States
(12) Patent Application Publication
(10) Pub. No.: US 2025/0151224 A1
(43) Pub. Date: May 8, 2025

(54) MODULAR FITMENT ASSEMBLY FOR ELECTRICAL CONNECTION FIELD

(71) Applicant: Vertiv Corporation, Westerville, OH (US)

(72) Inventors: BALAR RAMPATI SINGH, Maharashtra (IN); AKSHAY SHAH, Maharashtra (IN)

(21) Appl. No.: 18/941,892

(22) Filed: Nov. 8, 2024

(30) Foreign Application Priority Data
Nov. 8, 2023 (IN) 202321076242

(51) Int. Cl. H05K 7/14; H01R 9/24; H05K 7/20

(52) U.S. Cl. CPC H05K 7/1457; H01R 9/2458; H01R 9/2491; H05K 7/1454; H05K 7/20127

(57) ABSTRACT

A modular fitment assembly for an electrical connection includes: a fitment bracket; at least one power unit; and a bullet nose block disposed on the fitment bracket, wherein the bullet nose block includes at least one first aperture configured to mate with a nose pin of the at least one power unit.

### CROSS REFERENCE TO RELATED APPLICATIONS

This U.S. Non-Provisional Patent Application claims the benefit of Indian Provisional Patent Application Ser. No. 20/232,1076242 titled “A Modular Fitment Assembly For Electrical Connection Field” filed Nov. 8, 2023, the entire disclosure of which is hereby incorporated by reference.

### FIELD

The present disclosure relates to DC power systems comprising a variety of shelf types including but not limited to DC-DC converters, inverter shelves, solar power shelves, rectifier shelves as well as incorporating battery units and DC distribution units.

### BACKGROUND

Within a power conversion and generation system, numerous power units are organized into stacks or shelves. These power units primarily serve as DC power converters, responsible for converting AC to DC or altering DC voltage levels (either stepping up or stepping down) as desired by various equipment's in connection.

Traditionally, these power units are configured in a shelf-like arrangement, stacked one above the other, and connected electrically through a conventional bus bar setup. These bus bars are typically affixed to the rear section of the power units to maintain interconnection. Typically, in data centers or processing industries, a substantial quantity of the power units is arranged in the form of shelves, consequently, accessing the rear portion of these shelves during installation or removal of the power units becomes challenging, leading to unwieldy maintenance and repair procedures.

Further, whenever a power unit needs to be added to or removed from the system, it necessitates a complete shutdown of the entire system. This extends the downtime and significantly impacts the operational efficiency.

### SUMMARY

An aspect of the disclosed embodiments includes an apparatus that includes a modular fitment assembly for an electrical connection. The modular fitment assembly includes: a fitment bracket; at least one power unit; and a bullet nose block disposed on the fitment bracket, wherein the bullet nose block includes at least one first aperture configured to mate with a nose pin of the at least one power unit.

### BRIEF DESCRIPTION OF THE ACCOMPANYING DRAWING

A modular fitment for electrical connection, of the present disclosure will now be described with the help of the accompanying drawing in which:

FIG. 1A and FIG. 1B illustrates a perspective isometric view of a conventional shelf-arrangement of a power conversion and generation system with traditional bus bar connection.

FIG. 2A, FIG. 2B and FIG. 2C illustrates perspective isometric a front view, a rear view and stack arrangement of the modular fitment bracket in accordance with the present disclosure.

FIG. 3A illustrates a perspective view of a bullet nose block in accordance with the present disclosure.

FIG. 3B illustrates a perspective slant view of a bullet nose block in accordance with the

present disclosure.

FIG. 4 illustrate a perspective view of a power unit in accordance with the present disclosure.

FIG. 5 illustrates a perspective isometric view of mounting of modular fitment assembly over a frame in accordance with the present disclosure.

FIG. 6 illustrates a perspective isometric view of the mounting of the power unit on to the frame in accordance with the present disclosure.

### DETAILED DESCRIPTION

Embodiments, of the present disclosure, will now be described with reference to the accompanying drawing.

Embodiments are provided so as to thoroughly and fully convey the scope of the present disclosure to the person skilled in the art. Numerous details are set forth, relating to specific components, and methods, to provide a complete understanding of embodiments of the present disclosure. It will be apparent to the person skilled in the art that the details provided in the embodiments should not be construed to limit the scope of the present disclosure. In some embodiments, well-known processes, well-known apparatus structures, and well-known techniques are not described in detail.

The terminology used, in the present disclosure, is only for the purpose of explaining a particular embodiment and such terminology shall not be considered to limit the scope of the present disclosure. As used in the present disclosure, the forms “a,” “an,” and “the” may be intended to include the plural forms as well, unless the context clearly suggests otherwise. The terms “comprises,” “comprising,” “including,” and “having,” are open ended transitional phrases and therefore specify the presence of stated features, elements, modules, units and/or components, but do not forbid the presence or addition of one or more other features, elements, components, and/or groups thereof.

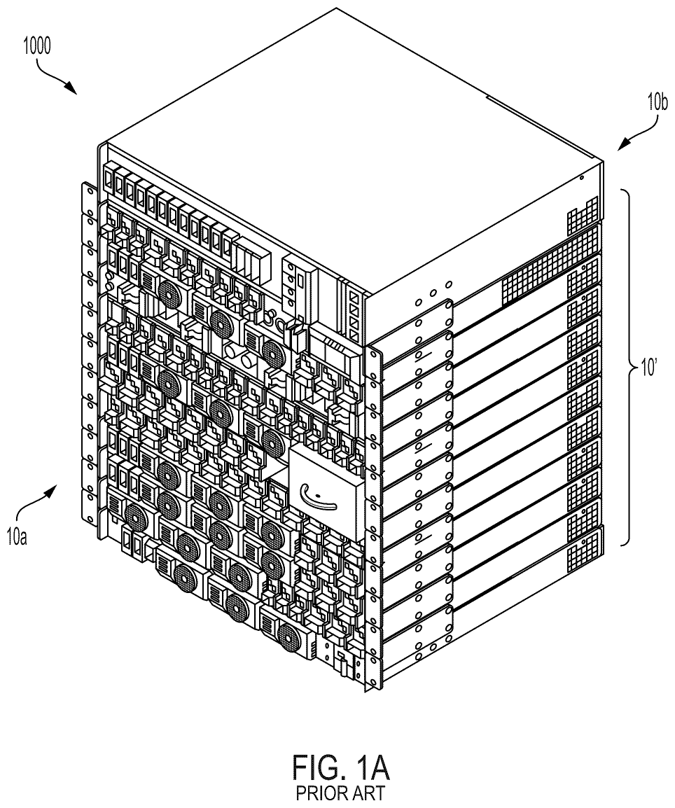

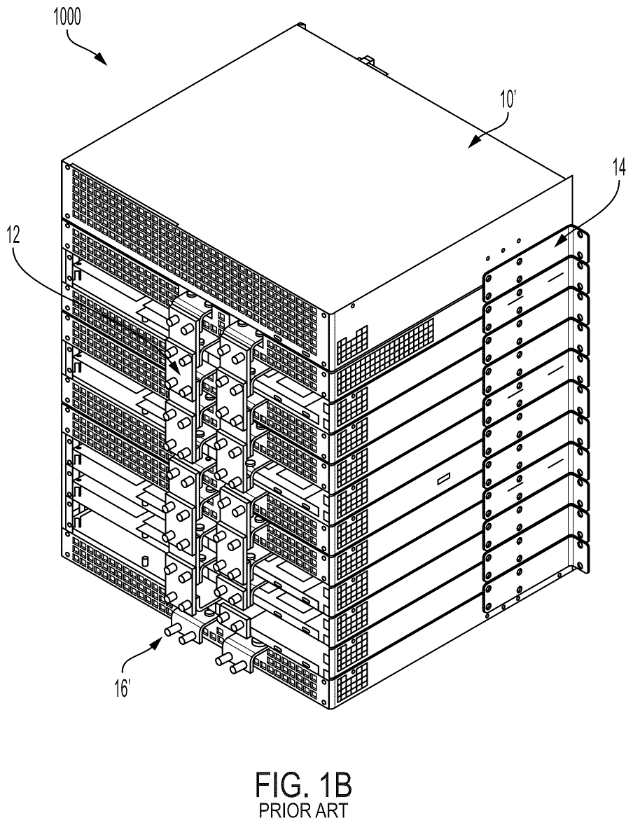

In a typical setup for the power conversion and generation systems (1000), the power units (10′) are organized in a shelf-like configuration, where they are stacked vertically and connected electrically using at least one conventional bus bar (12) setup. The power units (10′) are arranged in the form of shelves by means of a plurality of mounting brackets (14). These mounting brackets (14) are mounted at an operative side portion of the power units (10′) to keep one above another. This arrangement is depicted in FIG. 1A, and FIG. 1B, which provides a perspective isometric view of the traditional shelf layout connected by the conventional bus bar (12).

The typical conventional system is configured with a rearward connection arrangement which includes a busbar and stud assembly affixed through a bolted fastening mechanism. The rear portion of these power units (10) is equipped with at least a pair of nose pins, studs and bolts (16′).

Typically, these bus bars (12) are secured to the nose pins, studs and bolts (16′) of the power units (10) using various fasteners to ensure proper interconnection. Typically, in data centers or processing industries, a substantial number of power units (10) are often organized in this shelf-like manner. As a result, gaining access to the rear portion of these shelves for purposes like installation or removal of power units (10) can be quite challenging. This challenge leads to cumbersome maintenance and repair procedures. Further, whenever it becomes necessary to add or remove a power unit from the system, it typically requires a complete shutdown of the entire system. This shutdown extends the downtime significantly and has a substantial adverse impact on operational efficiency.

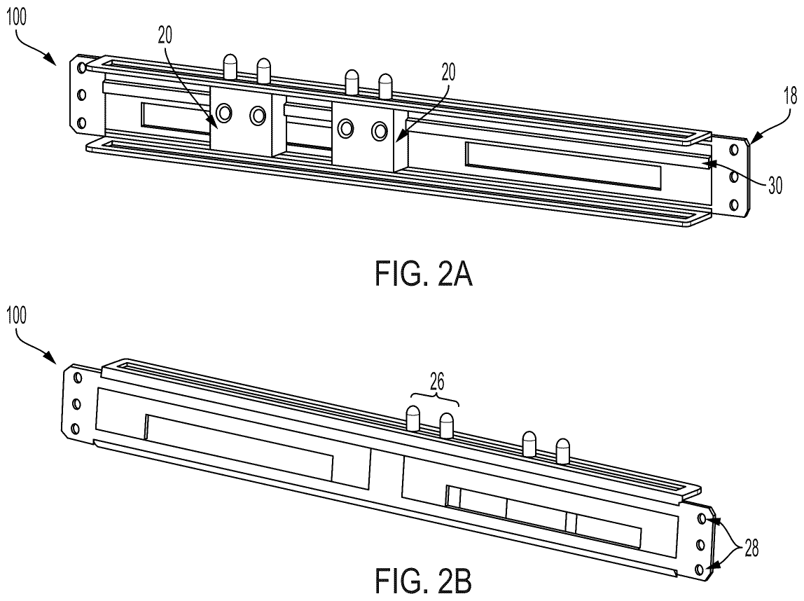

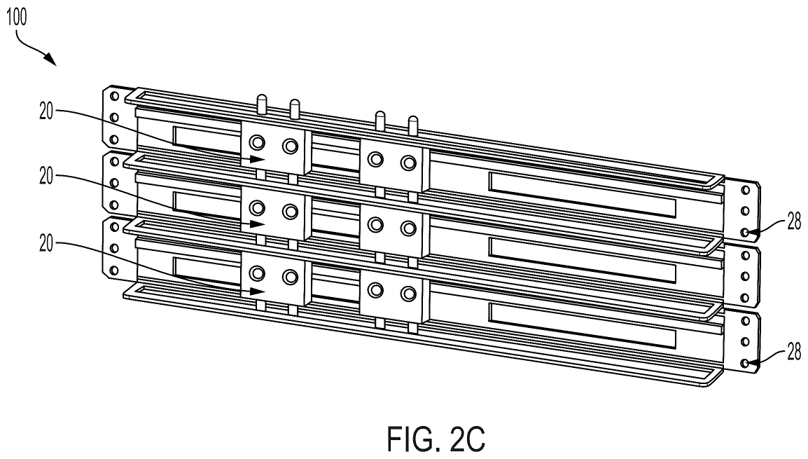

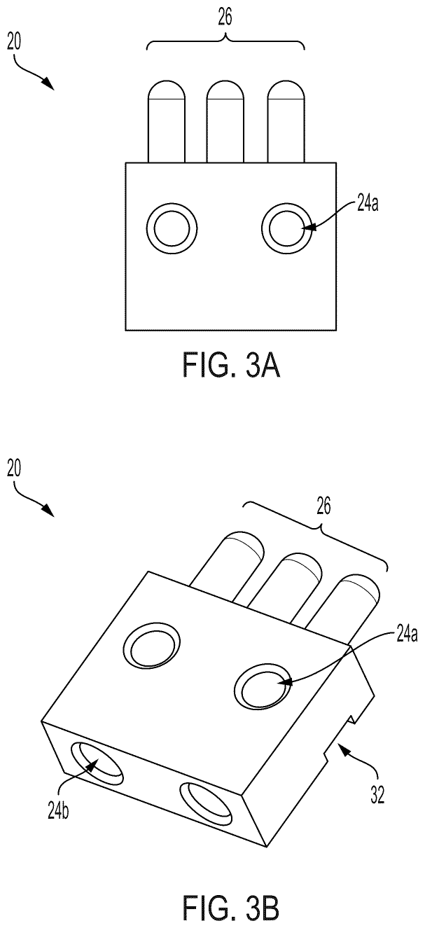

Therefore, the present disclosure envisages a modular fitment assembly for electrical connection (hereinafter referred as modular fitment 100). The present disclosure is explained with reference to FIG. 2-FIG. 6. FIG. 2A, FIG. 2B and FIG. 2C illustrate perspective isometric a front view, a rear view and stack arrangement of the modular fitment bracket in accordance with an embodiment of the present disclosure. The modular fitment assembly includes a fitment bracket with at least one bullet nose block (20) is operatively mounted thereon. The modular fitment is configured to be mounted on a frame which supports a plurality of power units (10) thereon. The plurality of power units (10) is mounted on the frame in the form of a shelves or stack. FIG. 3A illustrates a perspective view of a bullet nose block (20) in accordance with an embodiment of the present disclosure. FIG. 3B illustrates a perspective slant view of a bullet nose block (20) in accordance with an embodiment of the present disclosure.

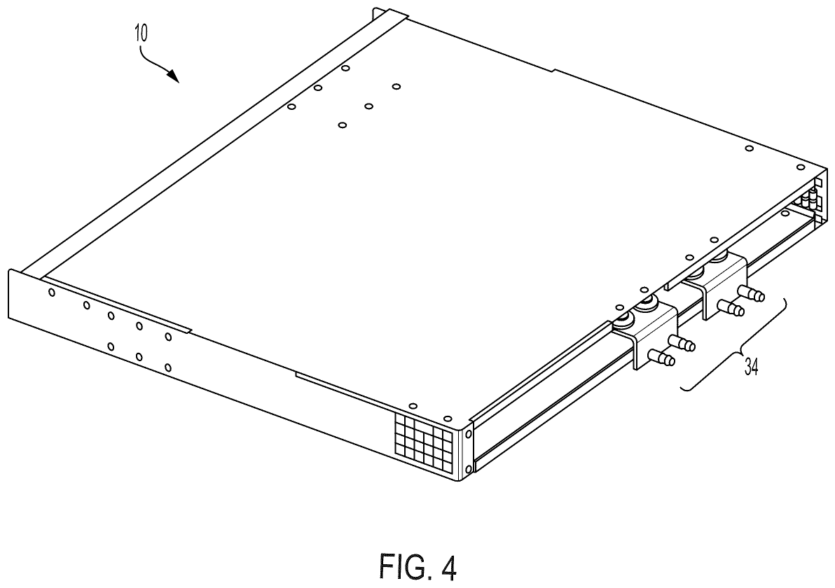

In an embodiment, each of the power unit includes at least one rectifier shelf, solar MPPT shelf, DC-DC converter shelf, inverter shelf, circuit breaker shelf, and different electrical components therein. FIG. 4 illustrate a perspective view of a power unit in accordance with an embodiment of the present disclosure.

In an embodiment, the fitment bracket may be defined by a U-shaped bracket with a pair of flange portion thereon. The space defined between the flange portions of the U-shaped bracket may be configured to hold and supports the bullet nose block (20) thereon.

In an embodiment, each of the flange portion may be configured with a guideway to slidably hold and guide the bullet nose block (20) thereon.

In an embodiment, an operative side portion of the bullet nose block (20) may be configured with a plurality of first apertures (24a) in relation to the number of nose pins (34) provided on the power units (10). The first apertures (24a) provided on the bullet nose block (20) can be configured to snap fit the nose pins (34). FIG. 4 illustrate a perspective view of the bullet nose block (20) in accordance with an embodiment of the present disclosure.

In an embodiment, the bullet nose block (20) may be configured with a plurality of 15 pins (26). The pins (26) may extend from an operative top portion of the bullet nose block (20).

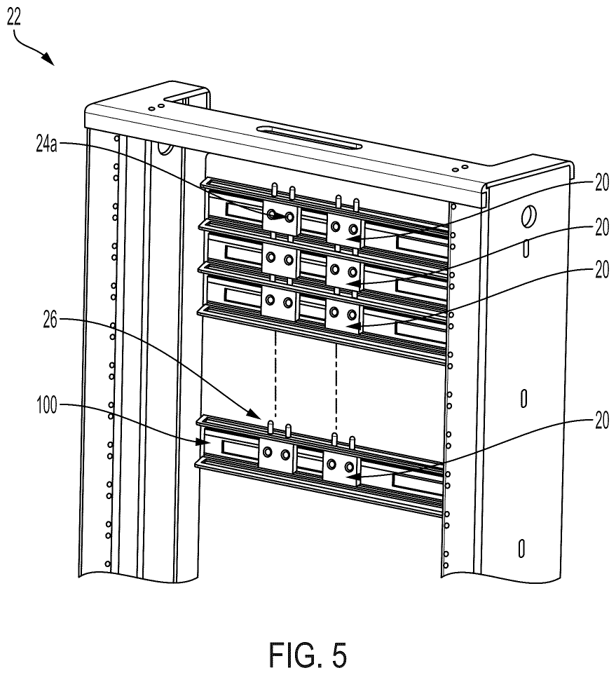

In an embodiment, the bullet nose block (20) may be configured with a plurality of second apertures (24b). The second apertures (24b) may be configured to receive the pins (26) from another bullet nose block (20) when the two modular fitments assembly (100) are mounted together in the form of stacks or shelves on the frame. FIG. 5 illustrates a perspective isometric view of mounting of modular fitment assembly over a frame in accordance with an embodiment of the present disclosure.

In an embodiment, the bullet nose block (20) is selected from a group of materials consisting of copper or a good heat conducting and electric conducting material having sufficient wear resistance.

In an embodiment, the fitment bracket may be configured with a fastening hole (28). The fastening hole (28) of the fitment bracket facilitates the mounting of the fitment bracket on an operative portion of the frame.

In an embodiment, an operative portion of the fitment bracket may be configured with at least one cut-out. Advantageously, the cut-out facilitates heat exchange between the operative portion of the power units (10) and the surrounding atmosphere.

In an embodiment, the fitment bracket can be selected from a group of materials consisting of polymeric material, a metal, a composite, or any combination thereof.

In an embodiment, an operative portion of the fitment bracket may be configured with a guide rail (30), and the operative portion of the bullet nose block (20) may be provided with at least one slot (32). In an operative configuration, the slot (32) portion of the bullet nose block (20) can abut on the guide rail (30) and thus can allow the sliding of the bullet nose block (20) in accordance with the position of the nose pins (34) along the longitudinal axis of the fitment bracket.

In an embodiment, the operative portion of the fitment bracket may be configured with a thermal insulation layer to prevent or substantially reduce heat transfer from the bullet nose block (20). In an embodiment, the thermal insulation material may be a ceramic, a polymer, a fiberglass material, or a non-conductive composite.

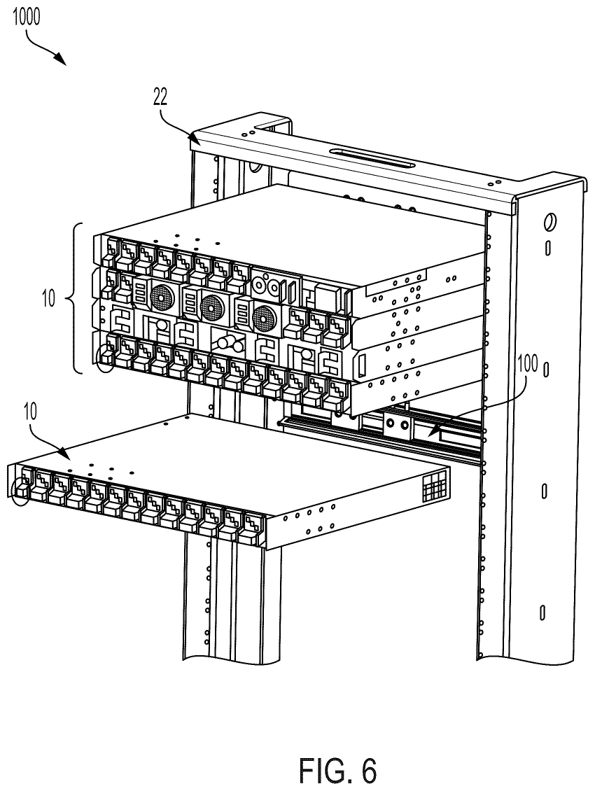

Advantageously, the nose pins (34) of the power unit can be snap fitted to the bullet nose block (20) of the fitment bracket. Therefore, the addition or removal of the power units (10) does not require a shutdown of the system, thereby improving system uptime and operational continuity. FIG. 6 illustrates a perspective isometric view of the mounting of the power unit on to the frame assembly in accordance with an embodiment of the present disclosure.

Further, the modular fitment assembly can also facilitate ease of maintenance and services and can simplify access to the power units (10) during assembly, disassembly, maintenance, and repair. Additionally, the modular fitment can enhance scalability and can ensure that additional power units (10) can be seamlessly integrated into the existing system without causing any power disruption.

The foregoing description of the embodiments has been provided for purposes of illustration and not intended to limit the scope of the present disclosure. Individual components of a particular embodiment are generally not limited to that particular embodiment, but are interchangeable. Such variations are not to be regarded as a departure from the present disclosure, and all such modifications are considered to be within the scope of the present disclosure.

In some embodiments, the systems and methods described herein may be configured to provide a modular fitment assembly for electrical connection, that, at least one of: minimizes the system shutdown so that the addition or removal of power units without requiring a complete system shutdown, thereby improving system uptime and operational continuity; facilitates ease of maintenance and services and simplifies access to power units during assembly, disassembly, maintenance, and repair, reducing downtime; enhances scalability and ensures that additional power units can be seamlessly integrated into the existing system without causing disruption; is compatible so as to cater to diverse equipment requirements; optimizes the utilization of space within the power conversion and generation setup, allowing for efficient stacking of power units while maintaining accessibility; promotes a cost-effective modular connection that minimizes the need for extensive hardware modifications or replacements; ensures seamless integration of the modular fitment into existing power unit configurations without necessitating significant alterations; is accessible from a front side and with no rear access required; and/or is mounted and installed to the power units.

In some embodiments, the systems and methods described herein may be configured to: ameliorate one or more problems of the prior art or to at least provide a useful alternative; provide a modular fitment assembly for electrical connection; provide a modular fitment assembly for electrical connection which can minimize the system shutdown so that the addition or removal of power units without requiring a complete system shutdown, thereby improving system uptime and operational continuity; provide a modular fitment assembly for electrical connection which can facilitate ease of maintenance and services and simplifies access to power units during assembly, disassembly, maintenance, and repair, reducing downtime; provide a modular fitment assembly for electrical connection which can enhance scalability and ensures that additional power units can be seamlessly integrated into the existing system without causing disruption; provide a modular fitment assembly for electrical connection which can be compatible so as to cater to diverse equipment requirements; provide a modular fitment assembly for electrical connection which can optimize the utilization of space within the power conversion and generation setup, allowing for efficient stacking of power units while maintaining accessibility; provide a cost-effective modular connection that minimizes the need for extensive hardware modifications or replacements; provide a modular fitment for electrical connection which can ensure seamless integration of the modular fitment into existing power unit configurations without necessitating significant alterations; provide a modular fitment for electrical connection which can be easily accessible from front side and no rear access is required; and/or provide a modular fitment for electrical connection which can be easily mounted and installed to the power units.

The foregoing disclosure has been described with reference to the accompanying embodiments which do not limit the scope and ambit of the disclosure. The description provided is purely by way of example and illustration.

The embodiments herein and the various features and advantageous details thereof are explained with reference to the non-limiting embodiments in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The foregoing description of the specific embodiments so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

Any discussion of devices, articles or the like that has been included in this specification is solely for the purpose of providing a context for the disclosure. It is not to be taken as an admission that any or all of these matters form a part of the prior art base or were common general knowledge in the field relevant to the disclosure as it existed anywhere before the priority date of this application.

While considerable emphasis has been placed herein on the components and component parts of the preferred embodiments, it will be appreciated that many embodiments can be made and that many changes can be made in the preferred embodiments without departing from the principles of the disclosure. These and other changes in the preferred embodiment as well as other embodiments of the disclosure will be apparent to those skilled in the art from the disclosure herein, whereby it is to be distinctly understood that the foregoing descriptive matter is to be interpreted merely as illustrative of the disclosure and not as a limitation.

1. An apparatus comprising:
a modular fitment assembly for an electrical connection that includes:
a fitment bracket;
at least one power unit; and
a bullet nose block disposed on the fitment bracket, wherein the bullet nose block includes at least one first aperture configured to mate with a nose pin of the at least one power unit.

2. The apparatus of claim 1, wherein the modular fitment assembly is configured to be mounted on a frame.

3. The apparatus of claim 2, wherein the frame supports the at least one power unit.

4. The apparatus of claim 1, wherein the at least one power unit includes at least one shelf.

5. The apparatus of claim 3, wherein the at least one shelf includes at least one of a rectifier shelf, a solar shelf, a DC-DC converter shelf, an inverter shelf, and a circuit breaker shelf.

6. The apparatus of claim 1, wherein the fitment bracket is defined by a U-shaped bracket having at least one flange portion.

7. The apparatus of claim 6, wherein the at least one flange portion includes a guideway configured to slidably hold and guide the bullet nose block.

8. The apparatus of claim 1, wherein the bullet nose block includes a plurality of pins.

9. The apparatus of claim 8, wherein each of the plurality of pins extend from an operative top portion of the bullet nose block.

10. The apparatus of claim 1, wherein the bullet nose block includes at least one second aperture.

11. The apparatus of claim 10, wherein the at least one second aperture is configured to receive at least one pin from at least one other bullet nose block.

12. The apparatus of claim 1, wherein the bullet nose block comprises a copper material.

13. The apparatus of claim 1, wherein the fitment bracket includes at least one fastening mechanism configured to facilitate mount of the fitment bracket on an operative portion of a frame.

14. The apparatus of claim 1, wherein the fitment bracket incudes at least one cut-out portion.

15. The apparatus of claim 14, wherein the at least one cut-out portion is configured to facilitate heat exchange the at least one power unit and an atmosphere associated with the at least one power unit.

16. The apparatus of claim 1, wherein the fitment bracket comprises one of a polymeric material, a metal material, and a composite material.

17. The apparatus of claim 1, wherein the fitment bracket includes at least one guide rail.

18. The apparatus of claim 17, wherein a portion of the bullet nose block includes at least one slot.

19. The apparatus of claim 18, wherein the at least one slot of the bullet nose block is configured to allow the bullet nose block to abut the guide rail, allowing the bullet nose block to slide along a longitudinal axis of the fitment bracket. 20 The apparatus of claim 1. wherein the fitment bracket includes a thermal insulation layer.
